(19) United States
(12) Patent Application Publication
(10) Pub. No.: US 2014/0370244 A1
(43) Pub. Date: Dec. 18, 2014

(54) COVER GLASS AND METHOD OF PRODUCING SAME

(71) Applicant: KONICA MINOLTA ADVANCED LAYERS, INC., Tokyo (JP)

(72) Inventor: Masaya Kinoshita, Nara-shi (JP)

(73) Assignee: KONICA MINOLTA, INC., TOKYO (JP)

(21) Appl. No.: 14/364,966

(22) PCT Filed: Dec. 4, 2012
(86) PCT No.: PCT/JP2012/081319

§ 371 Date: Jun. 12, 2014

(30) Foreign Application Priority Data
Dec. 14, 2011 (JP) 2011-273195

(51) Int. Cl. C03C 21/00; H05K 5/00

(52) U.S. Cl. CPC C03C 21/001; H05K 5/0017
USPC 428/177; 65/30.14

(57) ABSTRACT

A cover glass includes a glass formation member having a compressive stress layer formed at each of a front surface side and a rear surface side. The glass formation member includes: a central region; and a curved-surface region provided consecutively to an outer edge of the central region. The compressive stress layer in a region having the smallest approximated curvature radius R in a depressed-side region disposed at an inner side in the curve of the curved-surface region is formed to have a compressive stress layer depth with which a surface stress value thereof becomes higher than a surface stress value of the compressive stress layer formed in the central region and becomes a substantial peak.

### BACKGROUND

### Technical Field

The present invention relates to a cover glass having a portion formed to have a curved surface and a method of producing the cover glass.

As disclosed in Japanese Patent Laying-Open No. 2006-221810 (Patent Document 1), Japanese Patent Laying-Open No. 2004-339019 (Patent Document 2), and Japanese Patent Laying-Open No. 2008-247732 (Patent Document 3), there has been known a technique of improving the strength (surface stress value) of a surface of a glass by forming a compressive stress layer in the surface of the glass using an ion exchange method.

An electronic device such as a mobile phone or a tablet PC (Personal computer) includes a display having an image display unit. A glass plate, which has a surface chemically strengthened through formation of such a compressive stress layer therein, is provided as a cover glass (display cover glass) so as to cover the image display unit of the display. Such a cover glass incorporated into an electronic device (display device) such as a mobile phone is required to be thin and have a higher strength to endure impact caused by falling or the like.

In recent years, electronic devices (display devices) having touch panel type displays are becoming pervasive increasingly. Accordingly, the cover glasses, which have been unlikely to be pressed previously, are also more frequently pressed by users' fingers, pens, or the like. Also in view of such a circumstance, a cover glass having a higher strength is required.

Meanwhile, the cover glass chemically strengthened through the formation of the compressive stress layer is not limited to the use as the display cover glass for protection of the image display unit. Such a cover glass may be used as a member (so-called “exterior cover”) of a housing of an electronic device. Also in view of a circumstance in which devices with higher precision are currently provided in an electronic device at a higher density, the cover glass used as the exterior cover is required to have a higher strength.

### CITATION LIST

### Patent Document

PTD 1: Japanese Patent Laying-Open No. 2006-221810

PTD 2: Japanese Patent Laying-Open No. 2004-339019

PTD 3: Japanese Patent Laying-Open No. 2008-247732

### BRIEF SUMMARY

### Technical Problem

Now, it is assumed that a cover glass having a portion formed to have a curved surface is incorporated in an electronic device (display device) such as a mobile phone. The cover glass receives pressing force from a user or receives impact force caused by falling under various situations during use of the electronic device, for example, when wiping off stains on the display surface or the exterior surface or when repeatedly operating the display surface configured to serve as a touch panel. On this occasion, the stress on the cover glass is directly or indirectly exerted as bending stress also onto the portion formed to have the curved surface.

Now, it is assumed that during production of the cover glass, a compressive stress layer having a predetermined depth is formed in a surface (exposed surface such as the display surface or the exterior main surface) of the glass so as to attain a maximum strength (peak value) of the surface depending on the composition of the glass. The cover glass thus obtained is designed to attain the maximum strength in the surface, and serves as the display surface or exterior main surface having a high strength (rigidity) against externally applied stress.

Although the cover glass thus obtained is designed to attain an optimum value for the strength of the portion such as the display surface or the exterior main surface, the compressive stress layer is less likely to be formed in a region at an inner side in the curve of the portion formed to have the curved surface, as compared with that in the portion such as the display surface or the exterior main surface. The compressive stress layer formed in the region at the inner side in the curve has a thickness insufficient in value. A chemically strengthened glass is capable of maintaining a predetermined strength when given a scratch having a certain depth. However, when given a scratch having a depth exceeding the certain depth, the strength thereof becomes very weak. When the portion such as the display surface or the exterior main surface are repeatedly pressed by the user, a minute scratch in the region at the inner side in the curve of the portion formed to have the curved surface is grown due to stress concentration to result in generation of a crack or the like in the region at the inner side in the curve if the depth of the scratch exceeds a certain value.

The present invention has been made in view of the foregoing situation and has an object to provide a cover glass and a method of producing the cover glass, by each of which a predetermined strength can be maintained at its portion formed to have a curved surface.

### Solution to Problem

A cover glass based on the present invention includes a glass formation member having a compressive stress layer formed at each of a front surface side and a rear surface side thereof by performing chemical strengthening through ion exchange, the glass formation member including: a central region; and a curved-surface region provided consecutively to an outer edge of the central region and formed to be curved in a direction getting away from the front surface as the curved-surface region extends outwardly from the central region, the compressive stress layer in a region having the smallest approximated curvature radius R in a depressed-side region disposed at an inner side in the curve of the curved-surface region being formed to have a compressive stress layer depth with which a surface stress value thereof becomes higher than a surface stress value of the compressive stress layer formed in the central region and becomes a substantial peak.

Preferably, the compressive stress layer formed in the glass formation member is formed to have a thickness of not less than 20 μm and not more than 100 μm entirely in the glass formation member.

Preferably, the compressive stress layer formed in the central region has a depth deeper than a depth of the compressive stress layer formed in the depressed-side region of the curved-surface region.

Preferably, the cover glass is formed to entirely have a plate thickness in a range of not less than 0.4 mm and not more than 3.0 mm.

A method of producing a cover glass based on the present invention is a method of producing a cover glass having a compressive stress layer formed at each of a front surface side and a rear surface side thereof. The method includes the steps of: preparing a glass formation member including a central region and a curved-surface region provided consecutively to an outer edge of the central region and formed to be curved in a direction getting away from the front surface as the curved-surface region extends outwardly from the central region; preparing a storage bath having a chemical strengthening salt stored therein; and forming the compressive stress layer in the glass formation member at each of the front surface side and the rear surface side by immersing the glass formation member in the chemical strengthening salt, in the step of forming the compressive stress layer, chemical strengthening being performed such that the compressive stress layer in a region having the smallest approximated curvature radius R in a depressed-side region disposed at an inner side in the curve of the curved-surface region has a compressive stress layer depth with which a surface stress value thereof becomes higher than a surface stress value of the compressive stress layer formed in the central region and becomes a substantial peak.

Preferably, in the step of forming the compressive stress layer, the chemical strengthening is performed such that the compressive stress layer has a thickness of not less than 20 μm and not more than 100 μm entirely in the glass formation member.

Preferably, in the step of forming the compressive stress layer, the chemical strengthening is performed such that the compressive stress layer formed in the central region has a depth deeper than a depth of the compressive stress layer formed in the depressed-side region of the curved-surface region.

### Advantageous Effects of Invention

According to the present invention, there can be obtained a cover glass and a method of producing the cover glass, by each of which a predetermined strength can be maintained at its portion formed to have a curved surface.

### BRIEF DESCRIPTION OF THE DRAWINGS

FIG. 1 is a perspective view showing a disassembled state of a display device including a cover glass in an embodiment.

FIG. 2 is a cross sectional view taken along a line II-II in FIG. 1.

FIG. 3 is a cross sectional view showing an assembled state of the display device including the cover glass in the embodiment.

FIG. 4 is an enlarged cross sectional view showing a region surrounded by a line IV in FIG. 2.

FIG. 5 is a cross sectional view showing a state of the cover glass prior to chemical strengthening treatment in the embodiment.

FIG. 6 shows a relation between the depth of a compressive stress layer formed in a surface of a glass material used to produce the cover glass in the embodiment and the strength (surface stress value) of the surface.

FIG. 7 is a perspective view showing a storage bath used in a method of producing the cover glass in the embodiment.

FIG. 8 shows a relation between an immersion time of a glass formation member in an immersion step of the method of producing the cover glass in the embodiment and the formation depth of the compressive stress layer formed in the surface of the glass formation member.

FIG. 9 shows condition and result of an experiment performed with regard to the cover glass in the embodiment.

FIG. 10 is a cross sectional view showing the condition of the experiment performed with regard to the cover glass in the embodiment.

### DETAILED DESCRIPTION OF THE DRAWINGS AND THE PRESENTLY PREFERRED EMBODIMENTS

The following describes an embodiment based on the present invention with reference to figures. The scope of the present invention is not necessarily limited to the number, amount, and the like in the description of the embodiment unless otherwise specified. In the description of the embodiment, the same or corresponding components are given the same reference characters and may not be described repeatedly.

(Cover Glass 10)

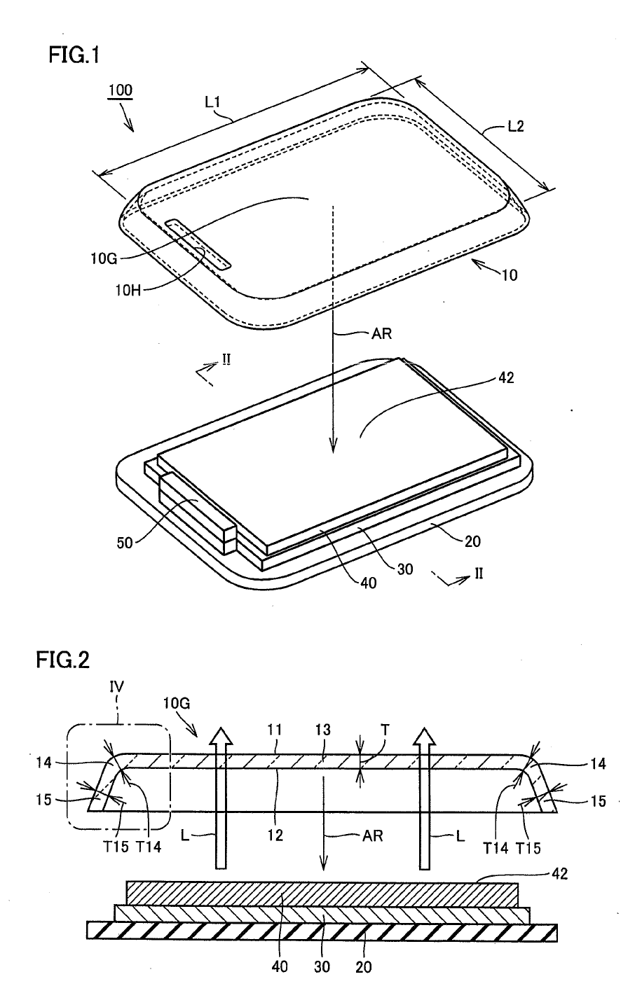

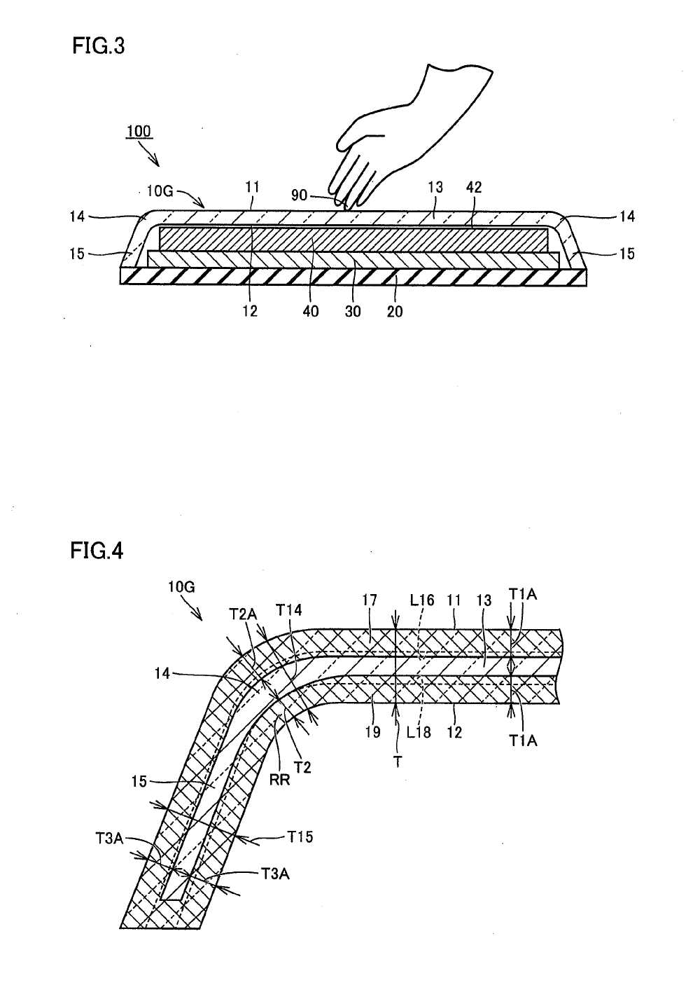

FIG. 1 is a perspective view showing a disassembled state of a display device 100 including a cover glass 10 in the present embodiment. FIG. 2 is a cross sectional view taken along a line II-II in FIG. 1. FIG. 3 is a cross sectional view showing an assembled state of display device 100. FIG. 4 is an enlarged cross sectional view showing a region surrounded by a line IV in FIG. 2.

As shown in FIG. 1, display device 100 includes: cover glass 10; an exterior plate 20 formed to have a plate-like shape; a circuit board 30 disposed on exterior plate 20; a display 40 mounted on circuit board 30; and a speaker 50 mounted on circuit board 30. Cover glass 10 in the present embodiment serves as a so-called “display cover glass”. As indicated by an arrow AR, cover glass 10 is attached onto exterior plate 20, thereby sealing circuit board 30, display 40, and speaker 50 on exterior plate 20.

Cover glass 10 includes: a glass formation member 10G provided to cover an image display unit 42 of display 40; and an opening 10H provided to correspond to speaker 50. Opening 10H is formed to extend through glass formation member 10G from the front surface 11 side (see FIG. 2) to the rear surface 12 side (see FIG. 2) thereof.

(Glass Formation Member 10G)

As shown in FIG. 1 and FIG. 2, glass formation member 10G of cover glass 10 includes: a central region 13 (see FIG. 2) formed in the form of a substantially flat plate; a curved-surface region 14 provided consecutively to the outer edge of central region 13 (see FIG. 2); and a side region 15 (see FIG. 2) provided consecutively to a side of curved-surface region 14 opposite to central region 13.

The outer edge of central region 13 in the present embodiment is formed to define a substantially rectangular shape with four rounded corner portions. Preferably, each of two facing sides (long sides) of central region 13 has a size L1 (see FIG. 1) of not less than 80 mm and not more than 250 mm and each of the other two facing sides (short sides) of central region 13 has a size L2 of not less than 50 mm and not more than 200 mm. Curved-surface region 14 is curved to be away from front surface 11 of central region 13 as it extends outwardly from central region 13. Side region 15 is disposed outwardly of curved-surface region 14 and is formed to have an annular shape as a whole.

Cover glass 10 (glass formation member 10G) in the present embodiment is configured such that thickness T of central region 13, thickness T14 of curved-surface region 14 (the thickness of curved-surface region 14 in the direction of a line normal to the front surface thereof), and thickness T15 of side region 15 have substantially the same value. Preferably, cover glass 10 may be formed such that each value of the plate thicknesses (thicknesses T, T14, and T15) is in the range of not less than 0.4 mm and not more than 3.0 mm entirely in cover glass 10.

As shown in FIG. 2 and FIG. 3, when cover glass 10 (glass formation member 10G) is attached onto exterior plate 20 (display 40), the front surface 11 (hereinafter, also referred to as “exposed surface”) side of cover glass 10 is exposed to outside.

Light L (see FIG. 2) passes through central region 13 of glass formation member 10G to the front surface 11 side from the rear surface 12 (hereinafter, also referred to as “non-exposed surface”) side of glass formation member 10G closer to image display unit 42, whereby the user recognizes various types of image information displayed on image display unit 42. In the case where front surface 11 of central region 13 is configured as a touch panel type display surface, front surface 11 of central region 13 is pressed by the user's finger 90 (see FIG. 3), a pen (not shown), or the like.

(Front-Side Compressive Stress Layer 17 and Rear-Side Compressive Stress Layer 19)

Referring to FIG. 4, in order to improve the strength of cover glass 10 (glass formation member 10G), a front-side compressive stress layer 17 is formed entirely in central region 13, curved-surface region 14, and side region 15 at the front surface 11 side of glass formation member 10G. Front-side compressive stress layer 17 is formed by ion exchange between alkali metal ions contained in the vicinity of front surface 11 of glass formation member 10G and ions of a chemical strengthening salt having an ionic radius larger than the ionic radius of the alkali metal ions.

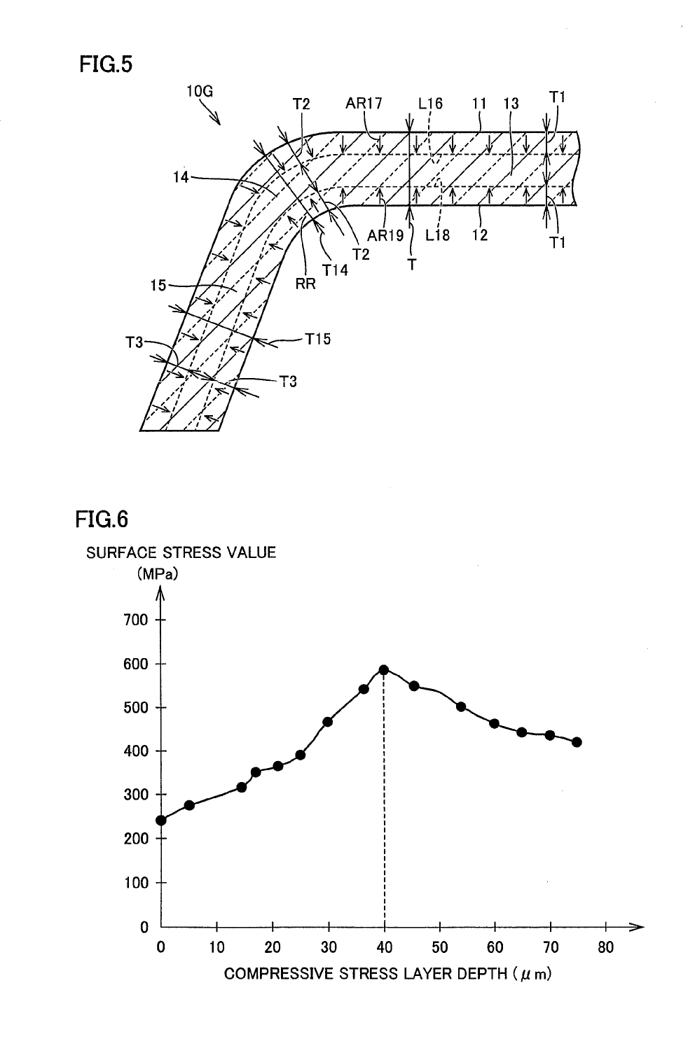

Although described in details later, front-side compressive stress layer 17 is formed in central region 13 at the front surface 11 side of glass formation member 10G to have a depth T1A (T1A>T1, where T1 will be described later with reference to FIG. 5). Front-side compressive stress layer 17 is formed in curved-surface region 14 at the front surface 11 side of glass formation member 10G to have a depth T2A (T2A>T2, where T2 will be described later with reference to FIG. 5). Front-side compressive stress layer 17 is formed in side region 15 at the front surface 11 side of glass formation member 10G to have a depth T3A (T3A>T3, where T3 will be described later with reference to FIG. 5).

Likewise, in order to improve the strength of cover glass 10 (glass formation member 10G), a rear-side compressive stress layer 19 is formed entirely in central region 13, curved-surface region 14, and side region 15 at the rear surface 12 side of glass formation member 10G. Rear-side compressive stress layer 19 is also formed by ion exchange between alkali metal ions contained in the vicinity of rear surface 12 of glass formation member 10G and ions of the chemical strengthening salt having an ionic radius larger than the ionic radius of the alkali metal ions.

Although described in details later, rear-side compressive stress layer 19 is formed in central region 13 at the rear surface 12 side of glass formation member 10G to have depth T1A (T1A>T1). Rear-side compressive stress layer 19 is formed in curved-surface region 14 (in particular, a region having the smallest approximated curvature radius R in a depressed-side region RR disposed at an inner side in the curve of curved-surface region 14) at the rear surface 12 side of glass formation member 10G to have depth T2. Rear-side compressive stress layer 19 is formed in side region 15 at the rear surface 12 side of glass formation member 10G to have depth T3A (T3A>T3).

As described above, as the depth of a compressive stress layer formed in a surface of a glass becomes deeper, the strength of the surface of the glass is improved. When the depth of the compressive stress layer formed in the surface of the glass reaches a predetermined value, the strength (surface stress value) of the surface of the glass becomes maximum. If the depth of the compressive stress layer formed in the surface of the glass becomes deeper, the strength of the surface of the glass begins to be decreased from the peak, i.e., the maximum value.

Glass formation member 10G of the present embodiment has curved-surface region 14. Depressed-side region RR is formed at an inner side (rear surface 12) in the curve of curved-surface region 14. Rear-side compressive stress layer 19 within the region having the smallest approximated curvature radius R in depressed-side region RR disposed at the inner side in the curve of curved-surface region 14 is formed to have a compressive stress layer depth (depth T2) with which the surface stress value thereof becomes higher than the surface stress value of the compressive stress layer formed in central region 13 and becomes the substantial peak.

FIG. 5 is a cross sectional view showing a state of cover glass 10 (glass formation member 10G) prior to the chemical strengthening treatment in the present embodiment. When front-side compressive stress layer 17 is formed in glass formation member 10G, which is in a state prior to being subjected to the chemical strengthening treatment, so as to have a depth indicated by an illustrative curve L16 represented by a dotted line in FIG. 5, the strength (surface stress value) of front surface 11 of glass formation member 10G becomes maximum. Likewise, when rear-side compressive stress layer 19 is formed in glass formation member 10G, which is in a state prior to being subjected to the chemical strengthening treatment, at the rear surface 12 side so as to have a depth indicated by an illustrative curve L18 represented by a dotted line in FIG. 5, the strength (surface stress value) of rear surface 12 of glass formation member 10G becomes maximum. It should be noted that each of the depths indicated by illustrative curve L16 and illustrative curve L18 is changed depending on the composition or the like of the glass used to prepare glass formation member 10G.

During the formation of front-side compressive stress layer 17 (see FIG. 4), ion exchange gradually takes place from the front surface 11 (exposed surface) side of each of central region 13, curved-surface region 14, and side region 15, thereby gradually forming front-side compressive stress layer 17 from the front surface 11 side toward the inner portion of glass formation member 10G (see an arrow AR17).

If front-side compressive stress layer 17 is formed in central region 13 to have the same depth as depth T1 indicated by illustrative curve L16 in central region 13, the strength (surface stress value) of front surface 11 of central region 13 becomes maximum. As described above, front-side compressive stress layer 17 having depth T1A (T1A>T1) is formed in central region 13 at the front surface 11 side of glass formation member 10G in the present embodiment.

If front-side compressive stress layer 17 is formed in curved-surface region 14 to have the same depth as depth T2 indicated by illustrative curve L16 in curved-surface region 14, the strength (surface stress value) of front surface 11 of curved-surface region 14 becomes maximum. As described above, front-side compressive stress layer 17 having depth T2A (T2A>T2) is formed in curved-surface region 14 at the front surface 11 side of glass formation member 10G in the present embodiment.

Likewise, if front-side compressive stress layer 17 is formed in side region 15 to have the same depth as depth T3 indicated by illustrative curve L16 in side region 15, the strength (surface stress value) of front surface 11 of side region 15 becomes maximum. As described above, front-side compressive stress layer 17 having depth T3A (T3A>T3) is formed in side region 15 at the front surface 11 side of glass formation member 10G in the present embodiment.

During the formation of rear-side compressive stress layer 19 (see FIG. 4), ion exchange gradually takes place from the rear surface 12 (non-exposed surface) side of each of central region 13, curved-surface region 14, and side region 15, thereby gradually forming rear-side compressive stress layer 19 from the rear surface 12 side toward the inner portion of glass formation member 10G (see an arrow AR19).

If rear-side compressive stress layer 19 is formed in central region 13 to have the same depth as depth T1 indicated by illustrative curve L18 in central region 13, the strength (surface stress value) of rear surface 12 of central region 13 becomes maximum. As described above, rear-side compressive stress layer 19 having depth T1A (T1A>T1) is formed in central region 13 at the rear surface 12 side of glass formation member 10G in the present embodiment.

When rear-side compressive stress layer 19 is formed in curved-surface region 14 to have the same depth as depth T2 indicated by illustrative curve L18 in curved-surface region 14, the strength (surface stress value) of rear surface 12 of curved-surface region 14 becomes maximum. As described above, rear-side compressive stress layer 19 is formed in curved-surface region 14 (in particular, the region having the smallest approximated curvature radius R in depressed-side region RR disposed at the inner side in the curve of curved-surface region 14) at the rear surface 12 side of glass formation member 10G to have depth T2 in the present embodiment. The region having the smallest approximated curvature radius R in depressed-side region RR is configured such that the strength (surface stress value) thereof becomes maximum (peak). Preferably, the compressive stress layer formed in central region 13 may have a depth deeper than depth T2 of the compressive stress layer formed in depressed-side region RR of curved-surface region 14.

If rear-side compressive stress layer 19 is formed in side region 15 to have the same depth as depth T3 indicated by illustrative curve L18 in side region 15, the strength (surface stress value) of rear surface 12 of side region 15 becomes maximum. As described above, side region 15 having depth T3A (T3A>T3) is formed in side region 15 at the rear surface 12 side of glass formation member 10G in the present embodiment.

Depending on the composition of the glass used to produce glass formation member 10G, depths T1, T2, T3 at the front surface 11 side and depths T1, T2, T3 at the rear surface 12 side may have the same values respectively or may have different values respectively. The values of depths T1, T2, T3 may be the same or may be different from one another.

FIG. 6 shows a relation between the depth of a compressive stress layer formed in a surface of the glass material of glass formation member 10G used to produce cover glass 10 in the present embodiment and the strength (surface stress value) of the surface.

As shown in FIG. 6, in glass formation member 10G used to produce cover glass 10 in the present embodiment, the strength (surface stress value) of each of central region 13, curved-surface region 14, and side region 15 at front surface 11 becomes maximum when each of depths T1, T2, T3 of front-side compressive stress layer 17 is 40 μm.

Likewise, in glass formation member 10G used to produce cover glass 10 in the present embodiment, the strength (surface stress value) of each of central region 13, curved-surface region 14, and side region 15 at rear surface 12 becomes maximum when each of depths T1, T2, T3 of rear-side compressive stress layer 19 is 40 μm.

It should be noted that each value of the depths of the compressive stress layer in the horizontal axis of FIG. 6 is a value measured using a polarimeter SF-IIC provided by Shinko Seiki Co., Ltd. Each of the surface stress values in the vertical axis of FIG. 6 is a value measured using a SURFACE STRESS METER “FSM-6000LE”, which is a glass surface stress meter provided by Orihara Manufacturing Ltd.

Referring to FIG. 4 and FIG. 5 again, as described above, front-side compressive stress layer 17 is formed in central region 13 at the front surface 11 side of glass formation member 10G so as to have depth T1A (T1A>T1). Front-side compressive stress layer 17 is formed in curved-surface region 14 at the front surface 11 side of glass formation member 10G so as to have depth T2A (T2A>T2). Front-side compressive stress layer 17 is formed in side region 15 at the front surface 11 side of glass formation member 10G so as to have depth T3A (T3A>T3).

Rear-side compressive stress layer 19 is formed in central region 13 at the rear surface 12 side of glass formation member 10G so as to have depth T1A (T1A>T1). Rear-side compressive stress layer 19 is formed in curved-surface region 14 (in particular, the region having the smallest approximated curvature radius R in the depressed-side region RR disposed at the inner side in the curve of curved-surface region 14) at the rear surface 12 side of glass formation member 10G so as to have depth T2. Rear-side compressive stress layer 19 is formed in side region 15 at the rear surface 12 side of glass formation member 10G so as to have depth T3A (T3A>T3).

In other words, front-side compressive stress layer 17 is formed in glass formation member 10G in the present embodiment to have a depth exceeding the compressive stress layer depth with which the surface stress value of glass formation member 10G at the front surface 11 side in each of central region 13, curved-surface region 14, and side region 15 becomes the substantial peak. Front-side compressive stress layer 17 of glass formation member 10G is not formed to have a formation depth along illustrative curve L16 (see FIG. 5), and is formed to be deeper than the depth indicated by illustrative curve L16.

Rear-side compressive stress layer 19 at the rear surface 12 side is formed to have a depth exceeding the compressive stress layer depth with which the surface stress value of glass formation member 10G at the rear surface 12 side becomes the substantial peak, except the region having the smallest approximated curvature radius R in depressed-side region RR disposed at the inner side in the curve of curved-surface region 14. Rear-side compressive stress layer 19 is not formed to have a formation depth along illustrative curve L18 (see FIG. 5), except the region having the smallest approximated curvature radius R in depressed-side region RR, and is formed to be deeper than the depth indicated by illustrative curve L18.

In contrast, rear-side compressive stress layer 19 in the region having the smallest approximated curvature radius R in depressed-side region RR disposed at the inner side in the curve of curved-surface region 14 is formed to have the compressive stress layer depth with which the surface stress value of glass formation member 10G at the rear surface 12 side becomes the substantial peak. Here, the expression “the compressive stress layer depth with which the surface stress value becomes the substantial peak” is intended to indicate a value in a range of ±5 μm of the compressive stress layer depth with which the surface stress value actually becomes the peak. In glass formation member 10G of the present embodiment, the surface stress value of rear-side compressive stress layer 19 in the region having the smallest approximated curvature radius R in depressed-side region RR is higher than the surface stress value of each of compressive stress layers 17, 19 formed in central region 13.

Now, it is assumed that display device 100 (see FIG. 3) falls, front surface 11 of glass formation member 10G is pressed by the user's finger 90, or front surface 11 is pressed by a pen or the like. In this case, not only stress is directly exerted on central region 13 (display surface) but also bending stress is indirectly exerted on curved-surface region 14 formed to have the curved surface.

In cover glass 10 of the present embodiment, rear-side compressive stress layer 19 in the region having the smallest approximated curvature radius R in depressed-side region RR disposed at the inner side in the curve of curved-surface region 14 is formed to have the compressive stress layer depth with which the surface stress value thereof becomes higher than the surface stress value of each of compressive stress layers 17, 19 formed in central region 13 and becomes the substantial peak.

Even if display device 100 falls or the user repeatedly presses touch panel type central region 13 (display surface) to result in concentration of stress in the region having the smallest approximated curvature radius R in depressed-side region RR, cracks or the like can be effectively suppressed from being generated in the region because the region is sufficiently chemically strengthened. Therefore, according to cover glass 10 of the present embodiment, a predetermined strength can be maintained in curved-surface region 14 formed to have the curved surface (in particular, the region having the smallest approximated curvature radius R in depressed-side region RR). Further, according to cover glass 10 of the present embodiment, the formation depth of each of compressive stress layers 17, 19 is deeper than the depth that provides the peak value. Hence, even if a deep scratch is formed in central region 13 (display surface) for example, a certain strength can be maintained.

Preferably, each of front-side compressive stress layer 17 and rear-side compressive stress layer 19 may be formed in glass formation member 10G to have a thickness (formation depths T1A, T2A, T3A, and T2) of not less than 20 μm and not more than 100 μm entirely in glass formation member 10G. The strength of cover glass 10 can be further improved as a whole.

(Method of Producing Cover Glass 10)

In cover glass 10 of the present embodiment, rear-side compressive stress layer 19 in the region having the smallest approximated curvature radius R in depressed-side region RR disposed at the inner side in the curve of curved-surface region 14 is formed to have the compressive stress layer depth with which the surface stress value thereof becomes higher than the surface stress value of each of compressive stress layers 17, 19 formed in central region 13 and becomes the substantial peak. In order to obtain cover glass 10, first, glass formation member 10G, which is a material (base material) of cover glass 10, is prepared. An example of the material of glass formation member 10G is soda glass.

Glass formation member 10G as the material may be obtained in the following manner: glass formation member 10G is formed by cutting a glass plate material; glass formation member 10G is formed through a so-called “re-heat press method” by forming a glass gob from a glass plate material and re-melting and then pressing the glass gob on a mold; or glass formation member 10G is formed through a so-called “direct press method” by dripping molten glass onto a lower mold and then pressing the molten glass by the lower mold and upper mold.

Glass formation member 10G prepared in the present embodiment is shaped as follows: thickness T (see FIG. 2) of central region 13 is 0.5 mm; and size L1 (see FIG. 1) and size L2 (see FIG. 1) of central region 13 are 110 mm×60 mm. Approximated curvature radius R of curved-surface region 14 at the rear surface 12 side (depressed-side region RR) is 1.0 mm. Thickness T15 of side region 15 is 1.6 mm.

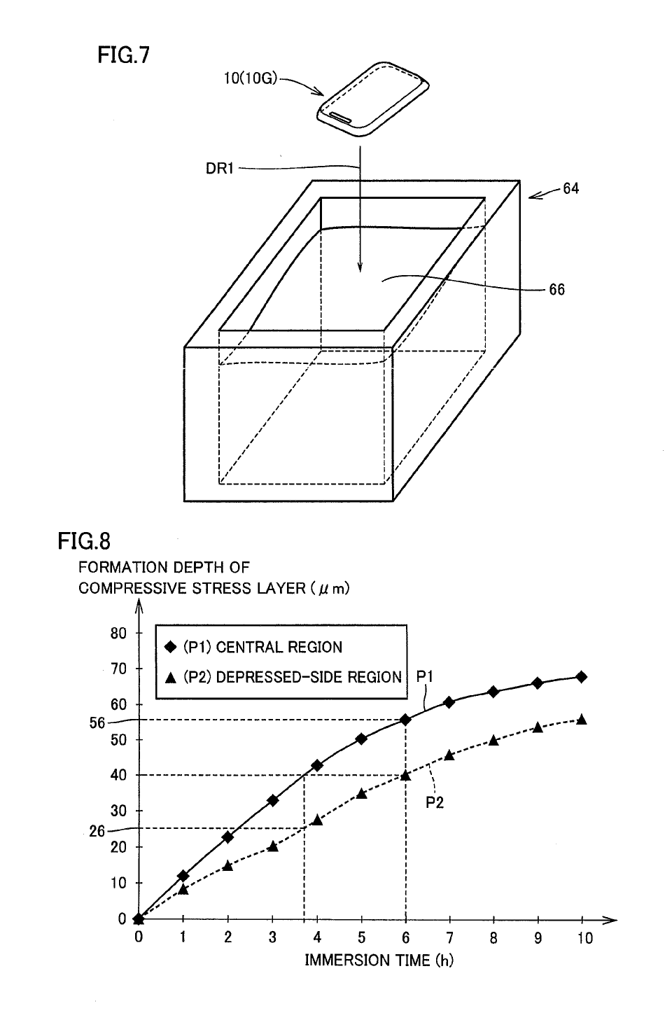

Referring to FIG. 7, next, a storage bath 64 having chemical strengthening salt 66 stored therein is prepared. Stored in storage bath 64 is chemical strengthening salt 66 such as potassium nitrate (purity of 98%). The inner wall of storage bath 64 having chemical strengthening salt 66 stored therein has a size of 300 mm×300 mm×300 mm, for example. A heating device (not shown) disposed around storage bath 64 is used to set the temperature of chemical strengthening salt 66 at about 400° C.

Glass formation member 10G is immersed in chemical strengthening salt 66 (see an arrow DR1). After passage of a predetermined immersion time, compressive stress layers 17, 19 are respectively formed in front surface 11 and rear surface 12 of glass formation member 10G.

Here, during the ion exchange (chemical strengthening), an amount of chemical strengthening salt supplied to depressed-side region RR is less than an amount of chemical strengthening salt supplied to regions other than depressed-side region RR. In depressed-side region RR (in particular, the region having the smallest approximated curvature radius R in depressed-side region RR), the chemical strengthening is less likely to take place. In other words, rear-side compressive stress layer 19 is less likely to be formed in depressed-side region RR (in particular, the region having the smallest approximated curvature radius R in depressed-side region RR).

A principle for this will be specifically described as follows. That is, using an ion diffusion coefficient D, a chemical strengthening time t, and a reference ion concentration C₀, an ion diffusion amount Q1 in the ion exchange can be expressed by the following formula (1):

Q1=2×C₀×√(D×t/π) Formula (1)

In other words, ion diffusion amount Q at a certain time is of a constant value per unit area in the surface. For example, in the case where the ion exchange is performed up to a depth R in an area of square having sides each having a size R, a required ion diffusion amount Q2 is expressed as the following formula (2):

Q2=R3 Formula (2)

Meanwhile, when bending only one side of the square by 90° in the form of an arc while maintaining the surface area at the same value as that of the square, an ion diffusion amount Q3 required for the area of the shape in response to the change in shape is expressed by the following formula (3):

Q3=R³×(1+(π/4)) Formula (3)

As understood from the above-described formula (3), when the ion exchange amount is constant, the ion exchange depth (the formation depth of the compressive stress layer) in depressed-side region RR (in particular, the region having the smallest approximated curvature radius R in depressed-side region RR) is shallower than that of a flat portion such as central region 13. Meanwhile, depressed-side region RR (in particular, the region having the smallest approximated curvature radius R in depressed-side region RR) is a portion that is likely to have the lowest strength due to its shape and that is likely to have a crack or the like generated therein.

Referring to FIG. 8, when the ion exchange amount is constant, the ion exchange depth (the formation depth of the compressive stress layer) in depressed-side region RR (the region having the smallest approximated curvature radius R in depressed-side region RR) is shallower than that of a flat portion such as central region 13. FIG. 8 shows a relation between the immersion time of glass formation member 10G in the immersion step of the method of producing cover glass 10 in the present embodiment and the formation depth of the compressive stress layer formed in the surface of glass formation member 10G.

As indicated by a curve P1, with passage of an immersion time of about 3.7 hours, compressive stress layers 17, 19 of about 40 μm are formed in central region 13 and the surface stress value of central region 13 becomes the peak (see FIG. 6). On the other hand, as indicated by a curve P2, even with the passage of an immersion time of about 3.7 hours, rear-side compressive stress layer 19 of about 26 μm is formed in the region having the smallest approximated curvature radius R in depressed-side region RR and the surface stress value of the region does not reach the peak.

In order to obtain cover glass 10 of the present embodiment, more immersion time is secured. As indicated by curve P2, with passage of an immersion time of about 6.0 hours, rear-side compressive stress layer 19 of about 40 μm is formed in the region having the smallest approximated curvature radius R in depressed-side region RR and the surface stress value of the region becomes the peak (see FIG. 6). On the other hand, as indicated by curve P1, with the passage of an immersion time of about 6.0 hours, compressive stress layers 17, 19 of about 56 μm are formed in central region 13 and the surface stress value of central region 13 does not become the peak (see FIG. 6).

Although the surface stress value of central region 13 does not become the peak, the surface stress value of the region having the smallest approximated curvature radius R in depressed-side region RR, which has the lowest strength due to its curved shape and is likely to have a crack or the like generated therein, can become the peak. In this way, cover glass 10 in the present embodiment can be obtained.

### EXPERIMENT EXAMPLE

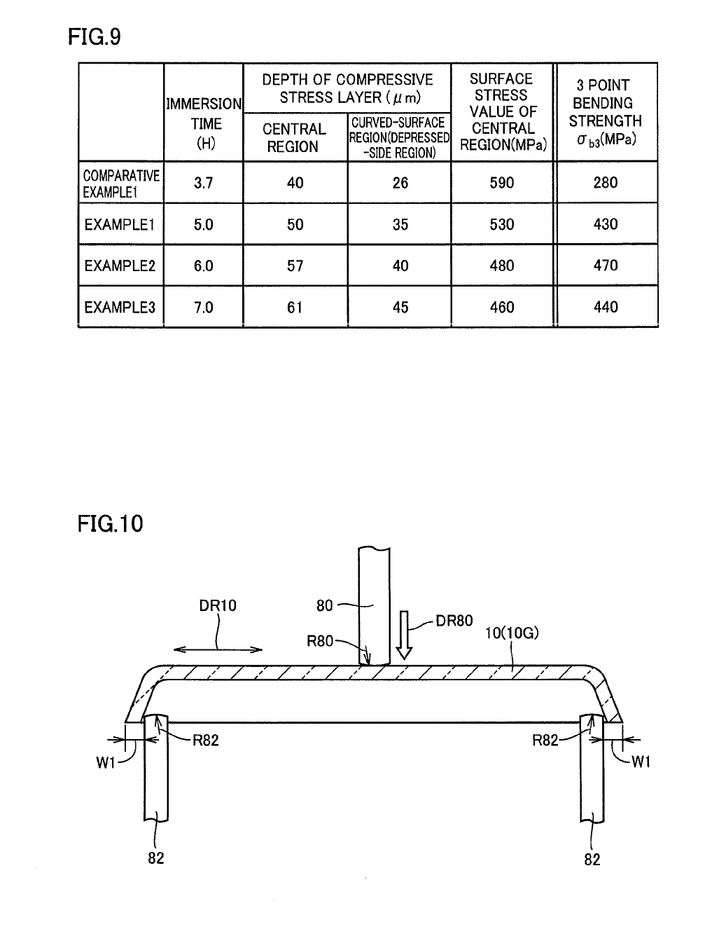

Referring to FIG. 9, the method of producing cover glass 10 based on the above-described embodiment was used to produce four types of cover glasses 10 of comparative example 1 and examples 1 to 3. The shape of glass formation member 10G used for each of comparative example 1 and examples 1 to 3 was the same as that in the above-described embodiment as follows: thickness T (see FIG. 2) of central region 13 was 0.5 mm; and size L1 (see FIG. 1) and size L2 (see FIG. 1) of central region 13 were 110 mm×60 mm. Approximated curvature radius R of curved-surface region 14 at the rear surface 12 side (depressed-side region RR) was 1.0 mm. Thickness T15 of side region 15 was 1.6 mm.

### Comparative Example 1

As comparative example 1, glass formation member 10G prepared as described above was immersed for 3.7 hours in storage bath 64 having chemical strengthening salt 66 stored therein. In cover glass 10 obtained using the production method based on comparative example 1, a compressive stress layer formed was of 40 μm in central region 13 and was of 26 μm in curved-surface region 14 (the region having the smallest approximated curvature radius R in depressed-side region RR).

The value of the formation depth of the compressive stress layer was measured using a polarimeter SF-IIC provided by Shinko Seiki Co., Ltd (the same applies to examples 1 to 3 described below). The surface stress value of central region 13 was 590 MPa. The surface stress value was measured using a SURFACE STRESS METER “FSM-6000LE”, which is a glass surface stress meter provided by Orihara Manufacturing Ltd (the same applies to examples 1 to 3 described below).

### Example 1

As example 1, glass formation member 10G prepared as described above was immersed for 5.0 hours in storage bath 64 having chemical strengthening salt 66 stored therein. In cover glass 10 obtained using the production method based on example 1, a compressive stress layer formed was of 50 μm in central region 13 and was of 35 μm in curved-surface region 14 (the region having the smallest approximated curvature radius R in depressed-side region RR). The surface stress value of central region 13 was 530 MPa.

### Example 2

As example 2, glass formation member 10G prepared as described above was immersed for 6.0 hours in storage bath 64 having chemical strengthening salt 66 stored therein. In cover glass 10 obtained using the production method based on example 2, a compressive stress layer formed was of 57 μm in central region 13 and was of 40 μm in curved-surface region 14 (the region having the smallest approximated curvature radius R in depressed-side region RR). The surface stress value of central region 13 was 480 MPa.

### Example 3

As example 3, glass formation member 10G prepared as described above was immersed for 7.0 hours in storage bath 64 having chemical strengthening salt 66 stored therein. In cover glass 10 obtained using the production method based on example 3, a compressive stress layer formed was of 61 μm in central region 13 and was of 45 μm in curved-surface region 14 (the region having the smallest approximated curvature radius R in depressed-side region RR). The surface stress value of central region 13 was 460 MPa.

Referring to FIG. 10, cover glass 10 obtained through the production method based on each of comparative example 1 and examples 1 to 3 was subjected to a 3 point bending strength measurement test. Specifically, supporting members 82, 82 were disposed to face each other with a space therebetween in the long side direction (DR10) of cover glass 10 and cover glass 10 was placed on and across their surfaces. When cover glass 10 was placed on supporting members 82, supporting members 82 were at positions displaced inwardly of the end portions of cover glass 10 by a size W1 (5 mm herein).

Each of supporting members 82 had a length of about 50 mm and had a tip portion that was formed in the form of a spherical shape only in the long side direction and that had a curvature radius R82 of 3.2 mm. After placing cover glass 10 on supporting members 82, a pressing member 80 was brought into abutment with the front surface of cover glass 10 (central region 13) at its central portion.

Pressing member 80 had a length of about 50 mm, and had a tip portion that was formed in the form of a spherical shape only in the long side direction and that had a curvature radius R80 of 3.2 mm. With pressing member 80 being in abutment with the front surface of cover glass 10 (central region 13), pressing member 80 was pressed into cover glass 10 at a speed of 0.5 mm/min (see an arrow DR80). Pressing member 80 was pressed down until cover glass 10 was broken.

Results as to the 3 point bending strength (see FIG. 9) were evaluated based on a value σ_{b3} given by the following formula:

σ_{b3}=(3PL)/(2wt2)

where P represents the maximum load (N) (load upon the breakage), L represents an interval between supporting members 82, 82, w represents the width of cover glass 10, and t represents the plate thickness of cover glass 10.

As shown in FIG. 9, as evaluation value σ_{b3} for the 3 point bending strength of cover glass 10 obtained through the production method based on comparative example 1, 280 MPa was obtained.

On the other hand, as evaluation value σ_{b3} for the 3 point bending strength of cover glass 10 obtained through the production method based on example 1, 430 MPa was obtained. As evaluation value σ_{b3} for the 3 point bending strength of cover glass 10 obtained through the production method based on example 2, 470 MPa was obtained. As evaluation value σ_{b3} for the 3 point bending strength of cover glass 10 obtained through the production method based on example 3, 440 MPa was obtained.

In comparison among the experiment results of comparative example 1 and examples 1 to 3, it is understood that evaluation value σ_{b3} for the 3 point bending strength can be made high by forming rear-side compressive stress layer 19 in the region having the smallest approximated curvature radius R in depressed-side region RR such that rear-side compressive stress layer 19 has a compressive stress layer depth with which the surface stress value thereof becomes higher than the surface stress value of each of compressive stress layers 17, 19 formed in central region 13 and becomes the substantial peak (±5 μm of the depth of 40 μm, which provides the peak value).

Further, assuming that evaluation value σ_{b3} of 470 MPa for the 3 point bending strength of example 2 is the peak, evaluation value σ_{b3} of 430 MPa for the 3 point bending strength in example 1 and evaluation value σ_{b3} of 440 MPa for the 3 point bending strength of example 3 are in the range of 10% of 470 MPa for example 2. Thus, it is understood that according to cover glass 10 in the present embodiment, a predetermined strength can be maintained in the portion formed to have the curved surface.

Heretofore, the embodiment and experiment example based on the present invention have been illustrated, but the embodiment and experiment example disclosed herein are illustrative and non-restrictive in any respect. For example, the above-described embodiment and experiment example have been illustrated based on the cover glass used as the so-called “display cover glass” covering the image display unit, but the present invention is not limited to the application for the display and can be applied as an exterior cover (a portion of an exterior of an electronic device or the like). Therefore, the technical scope of the present invention is defined by the terms of the claims, and is intended to include any modifications within the scope and meaning equivalent to the terms of the claims.

### REFERENCE SIGNS LIST

10: cover glass; 10G: glass formation member; 10H: opening; 11: front surface; 12: rear surface; 13: central region; 14: curved-surface region; 15: side region; 17: front-side compressive stress layer; 19: rear-side compressive stress layer; 20: exterior plate; 30: circuit board; 40: display; 42: image display unit; 50: speaker; 64: storage bath; 66: chemical strengthening salt; 80: pressing member; 82: supporting member; 90: finger; 100: display device; AR, AR17, AR19, DR1, DR80: arrow; L: light; L1, L2, W1: size; L16, L18: illustrative curve; P1, P2: curve; R80, R82: curvature radius; RR: depressed-side region; T, T14, T15: thickness; T1, T2, T3, T1A, T2A, T3A: depth.

1. A cover glass comprising a glass formation member having a compressive stress layer formed at each of a front surface side and a rear surface side thereof by performing chemical strengthening through ion exchange,
said glass formation member including:
a central region; and
a curved-surface region provided consecutively to an outer edge of said central region and formed to be curved in a direction getting away from the front surface as said curved-surface region extends outwardly from said central region,
said compressive stress layer in a region having the smallest approximated curvature radius R in a depressed-side region disposed at an inner side in the curve of said curved-surface region being formed to have a compressive stress layer depth with which a surface stress value thereof becomes higher than a surface stress value of said compressive stress layer formed in said central region and becomes a substantial peak.

2. The cover glass according to claim 1, wherein said compressive stress layer formed in said glass formation member is formed to have a thickness of not less than 20 μm and not more than 100 μm entirely in said glass formation member.

3. The cover glass according to claim 1, wherein said compressive stress layer formed in said central region has a depth deeper than a depth of said compressive stress layer formed in said depressed-side region of said curved-surface region.

4. The cover glass according to claim 1, wherein the cover glass is formed to entirely have a plate thickness in a range of not less than 0.4 mm and not more than 3.0 mm.

5. A method of producing a cover glass having a compressive stress layer formed at each of a front surface side and a rear surface side thereof, comprising the steps of:
preparing a glass formation member including a central region and a curved-surface region provided consecutively to an outer edge of said central region and formed to be curved in a direction getting away from the front surface as said curved-surface region extends outwardly from said central region;
preparing a storage bath having a chemical strengthening salt stored therein; and
forming said compressive stress layer in said glass formation member at each of said front surface side and said rear surface side by immersing said glass formation member in said chemical strengthening salt,
in the step of forming said compressive stress layer, chemical strengthening being performed such that said compressive stress layer in a region having the smallest approximated curvature radius R in a depressed-side region disposed at an inner side in the curve of said curved-surface region has a compressive stress layer depth with which a surface stress value thereof becomes higher than a surface stress value of said compressive stress layer formed in said central region and becomes a substantial peak.

6. The method of producing the cover glass according to claim 5, wherein in the step of forming said compressive stress layer, said chemical strengthening is performed such that said compressive stress layer has a thickness of not less than 20 μm and not more than 100 μm entirely in said glass formation member.

7. The method of producing the cover glass according to claim 5, wherein in the step of forming said compressive stress layer, said chemical strengthening is performed such that said compressive stress layer formed in said central region has a depth deeper than a depth of said compressive stress layer formed in said depressed-side region of said curved-surface region.
